(19) United States
(12) Patent Application Publication
(10) Pub. No.: US 2003/0121475 A1
(43) Pub. Date: Jul. 3, 2003

(54) Wafer support and peripheral parts thereof

(76) Inventors: Min-cheol Chu, Deajeon (KR); Kotoji Ando, Kanagawa (JP); Shigemi Satoh, Kanagawa (JP); Shinji Saitoh, Kanagawa (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/310,998

(22) Filed: Dec. 6, 2002

(30) Foreign Application Priority Data
Dec. 7, 2001 (JP) 2001-374655

(51) Int. Cl. C23C 16/00

(52) U.S. Cl. 118/725; 118/728

(57) ABSTRACT

A wafer support and peripheral parts thereof are used in a heating apparatus for semiconductor wafers and are made of a silicon nitride-silicon carbide ceramic composite containing 5 to 30 weight % silicon carbide. The wafer support and peripheral parts have superior crack healing characteristic in addition to superior thermal resistance, thermal shock resistance, and chemical stability.

### BACKGROUND OF THE INVENTION

### FIELD OF THE INVENTION

The present invention relates to a wafer support and to peripheral parts such as a ring, an arm, and a wall, which are used in a heating apparatus for carrying out anneal processing, oxidation processing, and diffusion processing on a semiconductor wafer in a semiconductor manufacturing process.

Semiconductor manufacturing requires processes such as annealing processing to heat a semiconductor wafer to a high temperature, oxidation processing, and diffusion processing. In these processes, as a means of heating various means such as a heating resistor, infrared ray lamp, and laser beam are used. In each apparatus, a heating process for heating to a high temperature of more than approximately 1000 degrees Celsius, and a cooling process, are repeated in a short time. Additionally, in recent years, techniques which perform the annealing process or the oxidation process by heating semiconductor wafers with high-output halogen lamp for an extremely short time have been developed. These techniques are called the RTPs (Rapid Thermal Processes), and apparatuses for applying this technique are used.

In these heating apparatuses, various parts such as wafer 1, support 2 of wafer 1, ring 3 to hold wafer 1, and arm 4 to transport wafer 1, and inner wall (a wall) 5 of the heating apparatus are required. FIG. 1 shows a schematic diagram of these parts. These parts require characteristics such as (1) thermal resistance to withstand processing temperatures over 1000 degrees Celsius, (2) thermal shock resistance to withstand rapid heating and rapid cooling, and (3) chemical stability so as not to contaminate the wafer.

At present, as materials of the wafer support and the peripheral parts thereof satisfying these requirements, silicon carbide (SiC) which is a ceramic of superior thermal resistance is mainly used.

However, there are the following problems in the wafer support and the peripheral parts thereof made of silicon carbide.

(1) When thermal shock resistance is insufficient, and a thermal shock of, or greater than, 500-600 degrees Celsius occur, the probability that damage will occur is high.

(2) Minute scratches and cracks occur on the surface of parts due to wearing in the processing when parts are produced and in the operating of parts. Therefore, when mechanical or thermal stress is applied, these scratches and cracks act as stress concentration parts. Thus, there are cases in which damage occurs due to stress which is much lower than the original strength of material would withstand.

### SUMMARY OF THE INVENTION

Accordingly, an object of the present invention is to provide a wafer support and peripheral parts thereof which have a superior crack healing characteristics in addition to superior thermal resistance, thermal shock resistance, and chemical stability.

In order to achieve this object, in accordance with the present invention, a wafer support and peripheral parts thereof are used in a heating apparatus for semiconductor wafer, and are made from a silicon nitride-silicon carbide ceramic composite that contains silicon carbide at 5 to 30 weight %.

In accordance with the present invention, it is possible to produce a wafer support and peripheral parts thereof which have higher strength and higher thermal shock resistance so that strength and thermal shock resistance of a silicon nitride-silicon carbide ceramic composite that contains silicon carbide at 5 to 30 weight % are superior in comparison to silicon carbide.

Additionally, in accordance with the present invention, it is possible to heal scratches and cracks that occur after processing or in operating by heat treating the wafer support and the peripheral parts, and to maintain good mechanical characteristic for a long time so that a silicon nitride-silicon carbide ceramic composite that contains silicon carbide at 5 to 30 weight % has satisfactory crack healing characteristic. That is, because the wafer support and peripheral parts thereof of the present invention have superior crack healing characteristics in addition to superior thermal resistance, thermal shock resistance, and chemical stability, it is possible to improve the mechanical reliability of parts. Furthermore, it is also possible to recover satisfactory mechanical reliability so that the crack healing characteristics by heat treating is exhibited even after these parts are used for a predetermined period.

In order to achieve this object, in accordance with the present invention, a wafer support and peripheral parts thereof can be subjected to crack heal by heat treatment at 800 to 1400 degrees Celsius after processing or after use.

In a conventional wafer support and peripheral parts which are made of silicon carbide, it is necessary to carry out the heat treatment at high temperatures, greater than or equal to 1400 degrees Celsius, in order to heal scratches or cracks which occur during the processing or during use. In contrast, in the wafer support and the peripheral parts thereof of the present invention, it is possible to obtain sufficient effects with a heat treatment in a temperature range of 800 to 1400 degrees Celsius. When the temperature of a heat treatment is less than 800 degrees Celsius, the effect of crack healing is not obtained, and on the other hand, when the temperature is over 1400 degrees Celsius, this is not appropriate because the oxidation of materials becomes extreme.

Additionally, it is difficult to strictly prescribe a range of appropriate time periods, so that the processing time of the heat treatment differs in accordance with various factors such as size of a product, shape, and temperature of heat treatment; however, a desirable range is approximately 0.5 to 10 hours. A longer heat treatment is required as the heat treatment temperature decreases or the product becomes larger, and in contrast a shorter heat treatment is required as the heat treatment temperature increases or the product size decreases.

Furthermore, in the present invention, a silicon nitride-silicon carbide ceramic composite which forms a wafer support and the peripheral parts thereof should contain silicon carbide at 5 to 30 weight %. When this content is less than 5 weight %, the strength and the thermal resistance of the wafer support and the peripheral parts containing the composite materials are not sufficient. On the other hand, when the content is over 30 weight %, the sintering characteristic are greatly reduced, and it is not possible to produce a fine sintered body.

Furthermore, in the present invention, it is preferable that the silicon nitride-silicon carbide ceramic composite contain a sintering additive at 1 to 10 weight %. When the content is less than 1 weight %, the effect of the sintering additive is not sufficiently obtained. On the other hand, when the content is greater than 10 weight %, the strength and the thermal resistance deteriorate so that surplus additive phase of the amorphous substance is generated. As the sintering additive, rare-earth oxide, such as alumina, yttria, etc., or components used in general as sintering additives of silicon nitride, such as silica, magnesia, calcia, or beryllia can be used. In the present invention, yttria is preferable among these components. Furthermore, a mixture of yttria and alumina at 9:1 to 4:6 weight ratio is most suitable as the sintering additive.

### BRIEF DESCRIPTION OF THE DRAWINGS

FIG. 1 is a perspective view of a wafer support and peripheral parts thereof in a heating apparatus of a semiconductor wafer;

FIG. 2 is a graph showing thermal shock resistances for specimens as an example of the present invention and a comparative example; and

FIG. 3 is a graph showing the relationship between surface-roughness and 4-point bending strength for a specimen of a first example of the present invention.

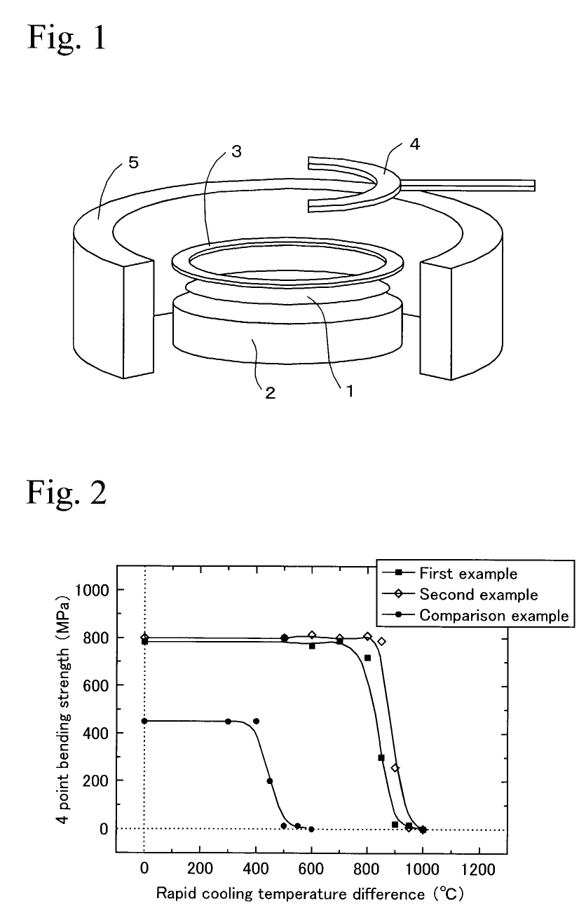

### DESCRIPTION OF THE PREFERRED EXAMPLES

A description will be given of an example in accordance with the present invention with reference to figures.

Next, an example based on the present invention and a comparative example will be described, and effects of the present invention will be clarified.

1. Manufacture of a Wafer Support

### FIRST EXAMPLE

Silicon nitride powder of average particle size 0.2 micrometer and silicon carbide powder of average particle size 0.27 micrometer were weighed so as to be 8:2 in weight ratio and mixed. Yttria at 8 weight % is added in the mixture powder as a sintering additive. A disc-form sintered body of approximately 6 mm thickness and approximately 330 mm diameter was made by sintering the powder at 1800 degrees Celsius by hot pressing in a nitrogen atmosphere. A wafer support of the First Example for a 12-inch wafer is made by machining the sintered body.

### SECOND EXAMPLE

Silicon nitride powder of average particle size 0.2 micrometer and silicon carbide powder of average particle size 0.27 micrometer were weighed so as to be 8:2 in weight ratio and mixed. Yttria at 5 weight % and alumina at 3 weight % are added in the mixture powder as a sintering additive. A disc-form sintered body of approximately 8 mm thickness and approximately 330 mm diameter was made by sintering the powder at 1800 degrees Celsius by hot pressing in a nitrogen atmosphere. A wafer support of the Second Example for a 12-inch wafer is made by machining the sintered body.

### COMPARATIVE EXAMPLE

Alumina at 2 weight % was added in silicon carbide powder of average particle size 0.27 micrometer as a sintering additive. A disc-form sintered body of approximately 8 mm thickness and approximately 330 mm diameter was made by sintering the powder at 2200 degrees Celsius by hot pressing in an argon atmosphere. A wafer support of the Comparative Example for a 12-inch wafer was made by machining this sintered body.

2. Evaluation Test of Wafer Support

(1) Thermal Shock Resistance Test

Specimens 3 mm thick, 4 mm wide, and 40 mm long were made from the wafer support which is obtained from each Example and Comparative Example as described. These specimens were maintained at a predetermined temperature in air, and then they were dropped into water to carry out rapid quenching. Thereafter, bending tests were carried out at room temperature according to a method in conformity with Japanese Industrial Standard JIS-R1601. These results are shown in FIG. 2. In accordance with this test, it was determined whether 4-point bending strength of specimens deteriorated at various temperature differences. Evaluation of the superiority and inferiority of thermal shock resistance was performed by using the temperature difference at which a strength reduction occurs. That is, it was decided that a specimen was superior material with respect to thermal shock resistance when the temperature difference at which strength reduction occurred became larger.

As a result of this test, in the Comparative Example made of silicon carbide, when rapid quenching was carried out at a temperature difference of approximately 500 degrees Celsius or more, 4-point bending strength sharply decreased, as is clear from FIG. 2. In contrast, in the First and Second Examples, a reduction in 4-point bending strength was not observed until rapid quenching of a temperature difference of approximately 800 degrees Celsius. Therefore, specimens made of the silicon nitride-silicon carbide ceramic composite, which includes 5 to 30 weight % silicon carbide, can endure greater sudden heating and cooling. Thus, it was demonstrated that the above-mentioned specimens can be used as wafer supports and peripheral parts for wafer heating apparatuses.

(2) Crack Healing Characteristic Test-1

To each specimen of the First and Second Examples and the Comparative Example, a pre-crack of a semicircular form of approximately 100 micrometer in radius was introduced on the tensile surface by a Vickers indenter. Then the specimens were divided into two groups, and the specimens of one group were subjected to a bending test in a method in conformity with JIS-R1601. The specimens of the other group were heat treated in air at temperatures ranging from 1200 degrees to 1400 degrees in Celsius. The specimens were subjected to a bending test of the above mentioned manner after the heat treatments.

As a result, in the specimens of Examples in which merely a pre-crack was produced, a strength which was only equal to or less than approximately 50% was obtained, in comparison with a smooth material which did not have a crack. Because the pre-crack acted as a stress concentration part, this result shows that destruction by a stress lower than that of the original material strength occurred. However, in the specimens of the First and Second Examples, the pre-cracks were healed and the bending strengths were recovered to the same level as those of smooth specimens which did not have cracks by heat treatments at 1200 degrees in Celsius. In contrast, the strength did not recover by heat treatment of 1200 degrees Celsius in a specimen made by silicon carbide of the Comparative Example, and it was observed that heat treatment at a high temperature greater than or equal to 1400 degrees Celsius was necessary in order for the strength to return to the same level as that of a smooth material which did not have a crack.

In specimens of the First Example and the Second Example, it was shown that the crack healing characteristic is exhibited by heating at low temperature in comparison with a specimen made of silicon carbide of the Comparative Example by these results. Additionally, in a specimen of the Second Example which contains yttria and alumina as sintering additives, it was shown that cracks were healed in a short time in comparison with a specimen of the First Example which contains only yttria as a sintering additive.

(3) Crack Healing Characteristic Test-2

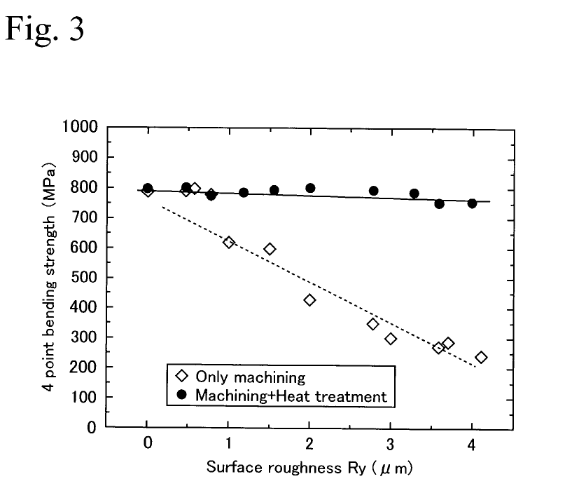

Grinding processing was carried out on the surfaces of specimens in each of the above-mentioned Examples and the Comparative Example by using various whetstones from #200 to #1000 to alter the surface roughness. Next, the relationship between the surface roughness and the 4-point bending strength was examined by carrying out bending tests on these specimens. Additionally, the 4-point bending strength was also measured for specimens subjected to the heat treatment for crack healing of 1300 degrees Celsius, for one hour in air, after having altered the surface roughness in the same way. Among these results, a result for the First Example is shown in FIG. 3.

As a result, the strength of specimens of the Examples that were not subjected to the heat treatment decreases as surface roughness increases. However, the strength of specimens of the Examples that were subjected to the heat treatment did not decrease even if the surface roughness were increased. In this manner, in Examples of the present invention, superior crack healing characteristics were produced by heat treatment.

What is claimed is:

1. A wafer support and peripheral parts thereof for a heating apparatus for semiconductor wafers, said wafer support and said peripheral parts thereof comprising a silicon nitride-silicon carbide ceramic composite containing silicon carbide at 5 to 30 weight %.

2. A wafer support and peripheral parts thereof as claimed in claim 1,
wherein said silicon nitride-silicon carbide ceramic composite contains sintering additive at 1 to 10 weight %.

3. A wafer support and peripheral parts thereof as claimed in claim 2, wherein said sintering additive contains at least yttria.

4. A wafer support and peripheral parts thereof as claimed in claim 2, wherein said sintering additive is composed of a mixture of yttria and alumina at a 9:1-4:6 weight ratio.

5. A wafer support and peripheral parts thereof as claimed in claim 1, 2, 3 or 4, wherein said wafer support and peripheral parts thereof undergo crack heal by heat treatment at 800 to 1400 degrees Celsius after processing or after use.
